(19) United States
(12) Patent Application Publication
(10) Pub. No.: US 2013/0256920 A1
(43) Pub. Date: Oct. 3, 2013

(54) SEMICONDUCTOR DEVICE

(71) Applicant: SUMITOMO ELECTRIC INDUSTRIES, LTD., Osaka-shi (JP)

(72) Inventors: Takahiro Sugimura, Osaka-shi (JP); Hiroshi Notsu, Osaka-shi (JP)

(73) Assignee: Sumitomo Electric Industries, Ltd., Osaka-shi (JP)

(21) Appl. No.: 13/852,836

(22) Filed: Mar. 28, 2013

Related U.S. Application Data
(60) Provisional application No. 61/619,011, filed on Apr. 2, 2012.

(30) Foreign Application Priority Data
Apr. 2, 2012 (JP) 2012-083707

(51) Int. Cl. H01L 23/48

(52) U.S. Cl. CPC H01L 23/48
USPC 257/777

(57) ABSTRACT

A semiconductor device in one embodiment includes a chip-mount substrate, a first semiconductor chip mounted on the chip-mount substrate, and a second semiconductor chip mounted adjacent to the first semiconductor chip on the chip-mount substrate.

The chip-mount substrate has a first surface on which the first semiconductor chip is mounted, and a second surface on which the second semiconductor chip is mounted. The second surface and the first surface are at different positions in a thickness direction of the chip-mount substrate.

### CROSS-REFERENCE TO RELATED APPLICATIONS

This application claims priority to Provisional Application Ser. No. 61/619011, filed on Apr. 2, 2012 and claims the benefit of Japanese

Patent Application No. 2012-083707, filed on Apr. 2, 2012, all of which are incorporated herein by reference in their entirety.

### FIELD

The present invention relates to a semiconductor device.

### RELATED BACKGROUND

An encased semiconductor device and a resin-sealed type semiconductor device are known examples of semiconductor devices (see “Technology for Evaluation of Failure Causes and Reliability Improvement of Wire Bonding Using Mainly Cu Wire” pp. 163 and 263, published by TECHNICAL INFORMATION INSTITUTE Co., Ltd., Jul. 29, 2011). In such devices, semiconductor chips mounted on the chip mounting board, or the die pad, are connected to electrode terminals via wires.

### SUMMARY

Multiple semiconductor chips may be mounted on a single chip-mount substrate to achieve required performance of the semiconductor device. The semiconductor chips are typically mounted on the chip-mount substrate via adhesive layers, such as solder bumps. To prevent an adhesive layer of one semiconductor chip from coming in contact with an adhesive layer of another semiconductor chip when the adjacent semiconductor chips are mounted, the chip-mount substrate is provided with a separation portion separating such adjacent adhesive layers, or solder bumps. This configuration necessitates a gap corresponding to the width of the separation portion between the adjacent semiconductor chips. It is thus difficult to mount a predetermined number of semiconductor chips on the chip-mount substrate to achieve required device performance, for example, in a miniaturized semiconductor device or a fixed size of chip-mount substrate due to device specifications.

An object of the present invention is to provide a semiconductor device that includes multiple semiconductor chips mounted on a chip-mount substrate with narrower gaps between adjacent chips.

One aspect of the present invention provides a semiconductor device including a chip-mount substrate, a first semiconductor chip that is mounted on the chip-mount substrate, and a second semiconductor chip that is mounted adjacent to the first semiconductor chip on the chip-mount substrate. The chip-mount substrate has a first surface on which the first semiconductor chip is mounted, and a second surface on which the second semiconductor chip is mounted. The second surface and the first surface are at different positions in a thickness direction of the chip-mount substrate.

The first semiconductor chip and the second semiconductor chip are mounted at different positions in the thickness direction of the chip-mount substrate. This configuration allows the first and the second semiconductor chips to be closer to each other in a direction perpendicular to the thickness direction of the chip-mount substrate.

In one embodiment of the present invention, the second surface may be at a higher position than the first surface in the thickness direction. In this case, a difference in the height of the position between the second surface and the first surface in the thickness direction may be equal to or greater than a thickness of the first semiconductor chip.

When the first and the second semiconductor chips are fixed on the chip-mount substrate using a conductive adhesive such as solder, this configuration prevents the adhesive for fixing the second semiconductor chip to the chip-mount substrate from coming in contact with the first semiconductor chip.

In one embodiment, the chip-mount substrate may include a connecting surface that connects the first surface and the second surface. The connecting surface may be perpendicular to the first surface.

This configuration enables the first and the second semiconductor chips mounted on the chip-mount substrate to be still closer to each other in a direction perpendicular to the thickness direction of the substrate.

In one embodiment, the chip-mount substrate may include a base plate, and a protrusion provided on a main surface of the base plate. The main surface may be the first surface, and a surface of the protrusion opposite to the base plate may be the second surface.

In this configuration, the second semiconductor chip is mounted on the protrusion of the chip-mount substrate to allow the first and the second semiconductor chips to be mounted at different positions in the substrate thickness direction.

In one embodiment, a material of the first semiconductor chip and the second semiconductor chip may include a wide bandgap semiconductor.

A semiconductor chip fabricated using a wide bandgap semiconductor has a lower production yield than a semiconductor chip fabricated using silicon (Si). In addition, a wide bandgap semiconductor is more expensive than a silicon semiconductor. Thus, fabricating a single large semiconductor chip using a wide bandgap semiconductor, as in the case of a silicon semiconductor, will result in a poor production yield and a high production cost. The use of a wide bandgap semiconductor will increase the necessity to mount a plurality of small semiconductor chips, instead of a single large semiconductor chip, onto a chip-mount substrate.

In the semiconductor device including the substrate having the first surface and the second surface at different positions in the thickness direction, the first semiconductor chip and the second semiconductor chip can be laid out efficiently. Thus, the configuration of the chip-mount substrate having the first surface and the second surface at different positions in the thickness direction is advantageous for the first semiconductor chip and the second semiconductor chip fabricated using a wide bandgap semiconductor.

As mentioned above, a semiconductor device of the present invention allows multiple semiconductor chips to be mounted on the chip-mount substrate with narrower gaps between adjacent chips.

### BRIEF DESCRIPTION OF THE DRAWINGS

FIG. 1 is a schematic plan view of a semiconductor device in accordance with a first embodiment of the present invention.

FIG. 2 is a schematic diagram illustrating the semiconductor chips being mounted on the die pad (chip-mount substrate).

FIG. 3A illustrates an example process of mounting two semiconductor chips on a die pad having no protrusion. FIG. 3B illustrates another example process of mounting two semiconductor chips on a die pad having no protrusion.

FIG. 4 illustrates an example process of mounting two semiconductor chips on a die pad having a protrusion.

FIG. 5 is a schematic view of a semiconductor device in accordance with a second embodiment of the present invention.

### DETAILED DESCRIPTION

Embodiments of the present invention will be described with reference to the drawings. The same components will be labeled with the same reference numerals throughout the drawings to omit redundant description thereof. The dimensional ratios in the drawings do not always correspond with those described herein. Terms indicating directions such as “upper” and “lower” are used for convenience of description based on the drawings.

### First Embodiment

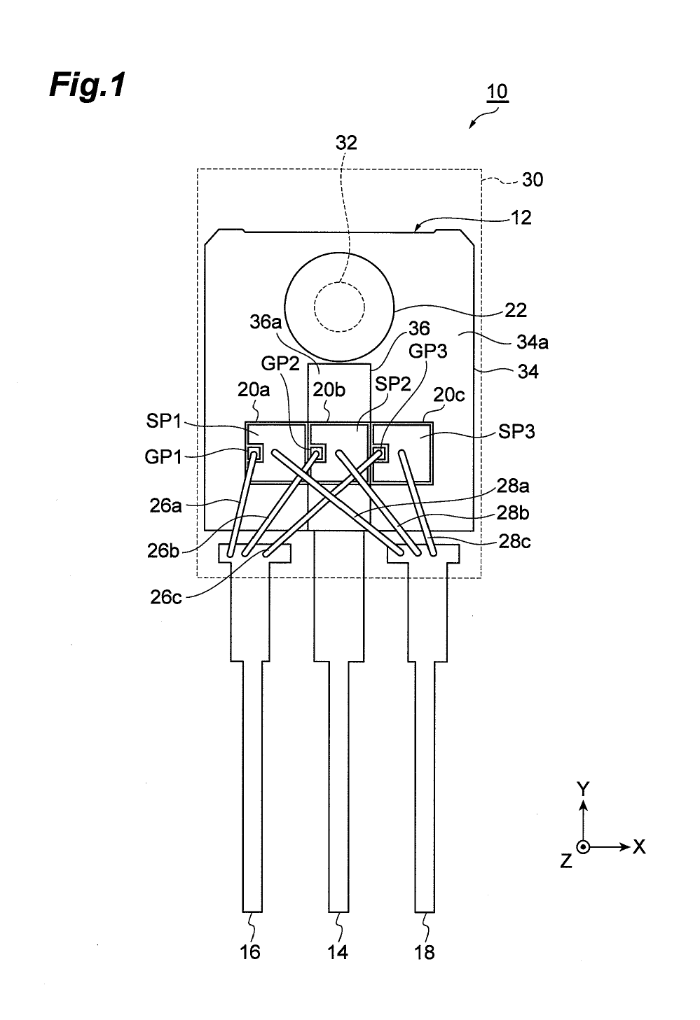

FIG. 1 is a schematic plan view of a semiconductor device in accordance with a first embodiment of the present invention. The semiconductor device 10 shown in FIG. 1 is a resin-sealed type semiconductor device. The semiconductor device 10 is a power semiconductor device used in, for example, a power supply. Examples of the package of the semiconductor device 10 include a common TO series. The TO series includes TO-247, TO-220, TO-263 (D2-PAK), and TO-252 (D-PAK).

The semiconductor device 10 includes a die pad 12, leads 14, 16, and 18, a semiconductor chip 20a (first semiconductor chip), a semiconductor chip 20b (second semiconductor chip), and a semiconductor chip 20c (first semiconductor chip).

The die pad 12 is a chip-mount substrate, on which the semiconductor chips 20a to 20c are mounted. The die pad 12 may be electrically connected to the semiconductor chips 20a to 20c. The die pad 12 may for example be rectangular as viewed from above (viewed in a pad thickness direction). Examples of the material of the die pad 12 include metals such as copper (Cu) and copper alloys. The die pad 12 may be provided with a through-hole 22, which penetrates the die pad 12 in the thickness direction. The through-hole 22 allows, for example, a screw to be placed therein to fasten the semiconductor device 10 to another member. Hereafter, the thickness direction of the die pad is referred to as Z direction, and two directions perpendicular to the Z direction are referred to as X direction and Y direction. The X direction and the Y direction are perpendicular to each other. When the die pad 12 is rectangular as viewed from above, the short-sided direction corresponds to the X direction, while the long-sided direction corresponds to the Y direction.

The leads 14, 16 and 18 are arranged in the X direction. The lead 14 is between the lead 16 and the lead 18. The leads 14, 16, 18 and the die pad 12 may constitute a lead frame. An inner end of the lead 14 is mechanically (or physically) integrated with the die pad 12. The die pad 12 is conductive, and thus the lead 14 and the die pad 12 are electrically connected. Examples of the material of the lead 14 include the same material as that of the die pad 12. The materials of the lead 16, 18 include metals such as copper and copper alloys.

The semiconductor chips 20a to 20c are mounted at predetermined positions on the die pad 12. In one example, the semiconductor chips 20a, 20b and 20c are arranged in the stated order in the X direction. Examples of the semiconductor chips 20a to 20c may be transistors such as metal oxide semiconductor field-effect transistors (MOS-FETs) and insulated gate bipolar transistors (IGBTs). Examples of the materials of the semiconductor chips 20a to 20c include wide bandgap semiconductors and silicon and other semiconductors. A wide bandgap semiconductor has a wider bandgap than silicon. Examples of the wide bandgap semiconductor include silicon carbide (SiC), gallium nitride (GaN), and diamond.

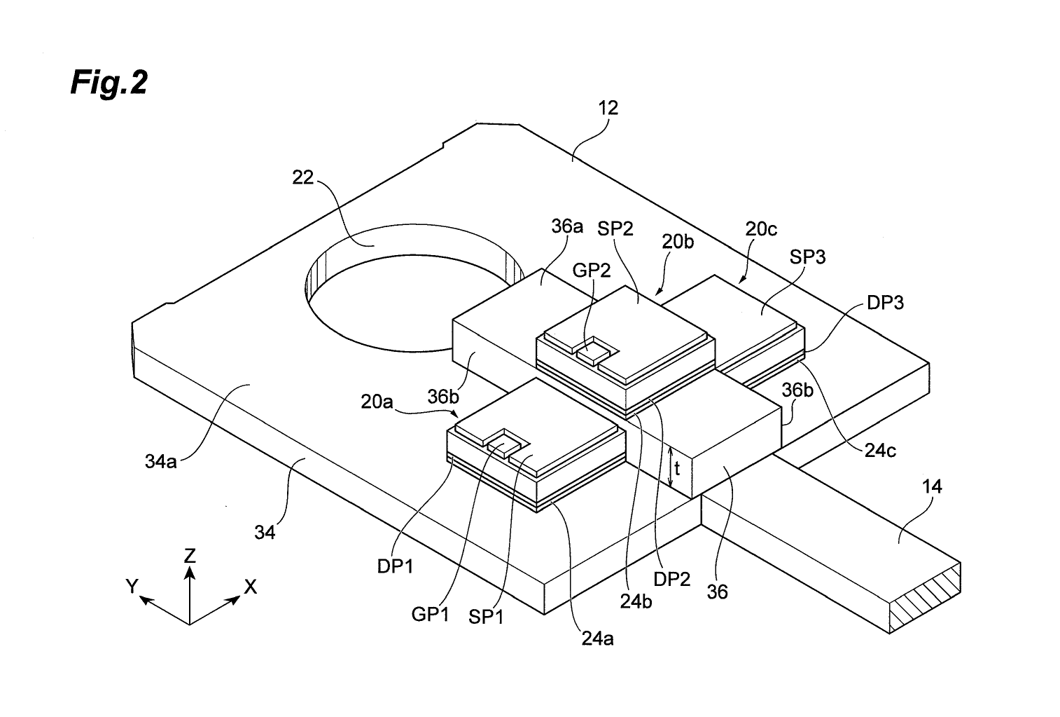

The semiconductor chip 20a includes a gate electrode pad GP1, an electrode pad SP 1, and a lower electrode DP 1 (see FIG. 2). Similarly, the semiconductor chip 20b includes a gate electrode pad GP2, an electrode pad SP2, and a lower electrode DP2 (see FIG. 2). Similarly, the semiconductor chip 20c includes a gate electrode pad GP3, an electrode pad SP3, and a lower electrode DP3 (see FIG. 2). The gate electrode pads GP1 to GP3 and the electrode pads SP1 to SP3 are arranged on the opposite side of the corresponding lower electrodes DP1 to DP3.

The lower electrodes DP1 to DP3 of the semiconductor chips 20a to 20c are mounted onto the die pad 12 via adhesive layers 24a to 24c (see FIG. 2), which may be made of lead-containing metal solder, lead-free metal solder, or conductive resin. The semiconductor chips 20a to 20c are thus electrically connected to the die pad 12.

The gate electrode pads GP1 to GP3 are connected to the lead 16 via wirings 26a to 26c. The electrode pads SP1 to SP3 are connected to the lead 18 via wirings 28a to 28c. The wirings 26a to 26c and 28a to 28c may be wires or ribbons. Examples of the material of the wirings 26a to 26c and 28a to 28c may be a metal such as aluminum, gold, or copper. The wirings 26a to 26c and 28a to 28c are connected to the leads 16 and 18 and to the semiconductor chips 20a to 20c by wire bonding using, for example, ultrasonic energy or pressure.

When the semiconductor chips 20a to 20c include MOS-FETs, the electrode pads SP1 to SP3 correspond to the source electrode pads, and the lower electrodes DP1 to DP3 correspond to the drain electrodes. In this case, the lead 14 corresponds to the drain electrode terminal, the lead 16 corresponds to the gate electrode terminal, and the lead 18 corresponds to the source electrode terminal. When the semiconductor chips 20a to 20c include IGBTs, the electrode pads SP1 to SP3 correspond to the emitter electrode pads, and the lower electrodes DP1 to DP3 correspond to the collector electrodes. In this case, the lead 14 corresponds to the collector electrode terminal, the lead 16 corresponds to the gate electrode terminal, and the lead 18 corresponds to the emitter electrode terminal. In the embodiment shown in FIG. 1, the semiconductor chips 20a to 20c are MOS-FETs.

The die pad 12 and the semiconductor chips 20a to 20c may be sealed by a resin portion 30. In FIG. 1, the resin portion 30 is indicated by a broken line for convenience of description. Inner ends of the leads 14, 16 and 18 are fixed to the resin portion 30. Parts of the leads 14, 16 and 18 inside the resin portion 30 are the so-called inner lead parts. Parts of the leads 14, 16 and 18 outside the resin portion 30 are the outer lead parts. The outer shape of the resin portion 30 may be a substantially rectangular parallelepiped. The material of the resin portion 30 may be a thermoplastic resin, such as polyphenylene sulfide (PPS) resin and a liquid crystal polymer. The resin portion 30 may be formed by molding the die pad 12 and the semiconductor chips 20a to 20c with the thermoplastic resin. The resin portion 30 may be provided with a through-hole 32, which shares the central axis with the through-hole 22 in the die pad 12. The through-hole 32, similar to the through-hole 22, allows a screw to be placed therein for fixation. The through-hole 32 has a smaller diameter than the through-hole 22.

FIG. 2 is a schematic diagram illustrating the semiconductor chips being mounted on the die pad. FIG. 2 also shows a part of the lead 14 schematically. The die pad 12 includes a base plate 34, and a protrusion 36 provided on a main surface (a first surface) 34a of the base plate 34. The protrusion 36 may be in the shape of a substantially rectangular parallelepiped extending in the Y direction. The length of the protrusion 36 in the X direction may be substantially equal to the width of the semiconductor chip 20b. The protrusion 36 is physically integrated with the base plate 34. The base plate 34 and the protrusion are formed integrally by, for example, injection molding. Alternatively, the die pad 12 having protrusion 36 may be cut out from a plate having a predetermined thickness. When the base plate 34 and the protrusion 36 are formed integrally, the lead 14 can be connected integrally to the base plate 34 at the same time.

The semiconductor chip 20b is mounted on an upper surface (a surface opposite to the base plate 34, or a second surface) 36a of the protrusion 36. The semiconductor chips 20a and 20c are arranged on the main surface 34a on the two sides of the protrusion 36 in the X direction. The upper surface 36a on which the semiconductor chip 20b is mounted is consequently higher in the Z direction than the main surface 34a on which the semiconductor chips 20a and 20c are mounted. In one embodiment, the thickness t of the protrusion 36 (its length in the Z direction) is greater than the thickness of the semiconductor chips 20a and 20c. The thickness t of the protrusion may be equal to or greater than the thickness of the semiconductor chips 20a and 20c. In one embodiment, side surfaces 36b (connecting surfaces) of the protrusion 36, which each connect the main surface 34a to the upper surface 36a, may be substantially perpendicular to the main surface 34a.

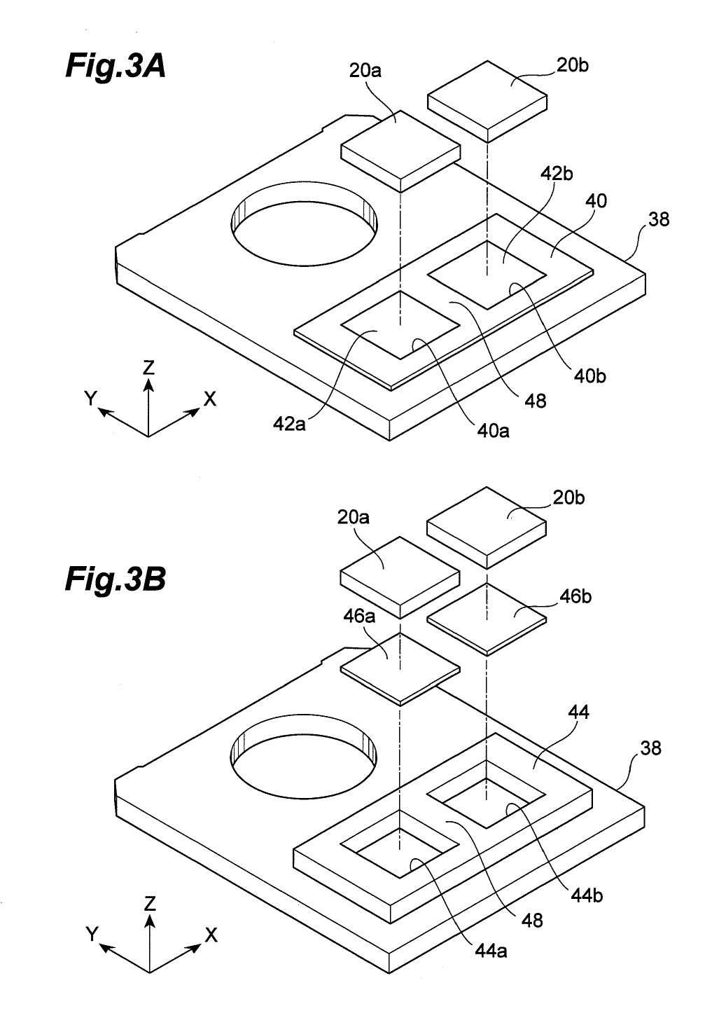

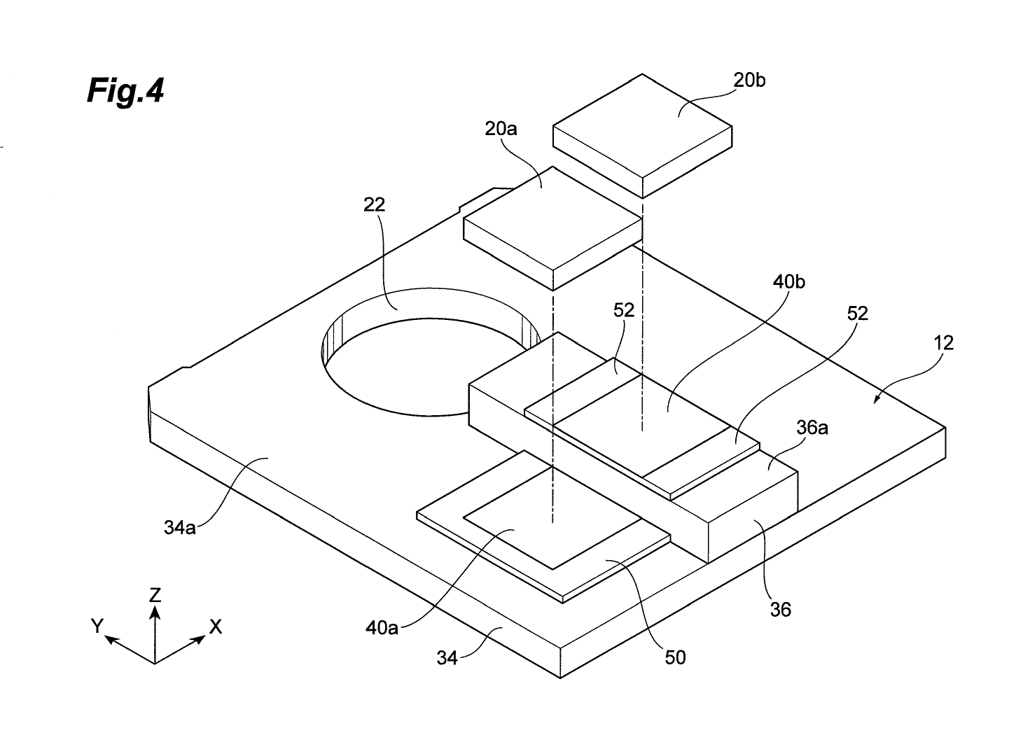

The die pad 12 having the protrusion 36 allows the semiconductor chips 20a to 20c to be arranged with narrower gaps between them in the X direction than a die pad having no protrusion 36, as shown in FIG. 1. This will be described with reference to FIGS. 3A and 3B and FIG. 4.

FIG. 3A illustrates an example process of mounting two semiconductor chips on a die pad having no protrusion, while FIG. 3B illustrates another example process of mounting two semiconductor chips on a die pad having no protrusion. FIG. 4 illustrates an example process of mounting two semiconductor chips on a die pad having a protrusion. FIGS. 3A, 3B, and 4 schematically illustrate the semiconductor chips and the die pad.

FIG. 3A illustrates die bonding, or a process for attaching the semiconductor chips 20a and 20b to a plate-like die pad 38 having no protrusion using a printing paste. A printing mask 40 having openings 40a and 40b with sizes corresponding to the sizes of the semiconductor chips 20a and 20b is formed at positions where the chips are to be mounted. Solder pastes 42a and 42b are applied in the openings 40a and 40b. Next, the semiconductor chips 20a and 20b are disposed on the solder pastes 42a and 42b. The solder pastes 42a and 42b are heated and cooled to attach the semiconductor chips 20a and 20b to the die pad 38. In this embodiment, the solder pastes 42a and 42b are the adhesive layers 24a and 24b.

FIG. 3B illustrates die bonding, or a process for mounting the semiconductor chips 20a and 20b on the die pad 38 using a mounting jig 44. In FIG. 3B, the mounting jig 44 is used instead of a printing mask.

The mounting jig 44 having openings 44a and 44b with sizes corresponding to the sizes of the semiconductor chips 20a and 20b is disposed on the die pad 38 at positions where the chips 20a and 20b are to be mounted. Solder bumps 46a and 46b are disposed in the openings 44a and 44b, respectively. Next, the semiconductor chips 20a and 20b are disposed on the solder bumps 46a and 46b. The solder bumps 46a and 46b are heated and cooled to attach the semiconductor chips 20a and 20b to the die pad 38. In this embodiment, the solder bumps 46 are the adhesive layers 24a and 24b.

In either process shown in FIG. 3A or FIG. 3B, a separation portion 48 is provided between the openings 40a and 40b, or between the openings 44a and 44b, to separate the solder paste 42a or the solder bump 46a for the semiconductor chip 20a from the solder paste 42b or the solder bump 46b for the semiconductor chip 20b. This necessitates a gap corresponding to the width of the separation portion 48 formed between the semiconductor chips 20a and 20b.

The die pad having the protrusion 36 allows the semiconductor chips 20a and 20b to be mounted at different height positions. This eliminates the separation portion 48 shown in FIG. 4. In this case, the solder pastes 42a and 42b, or the solder bumps 46a and 46b can be disposed on the main surface 34a and on the protrusion 36 without using the printing mask 40 or the mounting jig 44. Alternatively, as shown in FIG. 4, a U-shaped printing mask 50 may be disposed with its open-side end being in contact with the protrusion 36 to regulate the mounting position of the semiconductor chip 20a, and a pair of printing mask pieces 52 may be arranged to extend along the width of the protrusion 36 to regulate the mounting position of the semiconductor chip 20b. In this case, the solder pastes 42a and 42b, which enable die bonding of the semiconductor chips 20a and 20b, are formed in a region defined by the printing mask 50 and the protrusion 36 and between the mask pieces 52. After the solder pastes 42a and 42b are formed, the semiconductor chips 20a and 20b may be mounted on the die pad 12 as in the process shown in FIG. 3A. Although the process shown in FIG. 4 is described by focusing on the use of the printing mask 50, a mounting jig having the shape similar to that of the printing mask 50 may be used instead.

The protrusion 36 on the die pad 12 separates the semiconductor chip 20a from the semiconductor chip 20b in the Z direction. This prevents the solder pastes 42a and 42b (or the solder bumps 46a and 46b), which enable die bonding of the semiconductor chips 20a and 20b, from coming in contact with each other as described above with reference to FIG. 4. Thus, the separation portion 48, which is used to separate the semiconductor chips 20a and 20b during die bonding, can be eliminated. This minimizes the gap between the semiconductor chips 20a and 20b in the X direction.

Although the above description focuses on the gap between the semiconductor chip 20a and 20b in the X direction, the same applies to the gap between the semiconductor chip 20b and 20c in the X direction. The die pad having the protrusion 36 allows the gap in the X direction between two adjacent ones of the semiconductor chips 20a to 20C to be smaller than such a gap on the die pad having no protrusion 36. In this case, the mounting area of the semiconductor chips 20a to 20c can be reduced further.

Normally, the semiconductor chips 20a to 20c each have an inactive area surrounding an active area to have breakdown characteristics. Thus, the semiconductor chips 20a and 20c may be arranged in contact with the side surfaces of the protrusion 36. In this case, the semiconductor chips 20a and 20c each can be arranged to have substantially no gap with the semiconductor chip 20b in the X direction.

In an embodiment in which the protrusion 36 has a thickness that is equal to or greater than the semiconductor chips 20a and 20c, and specifically the protrusion 36 has a greater thickness than the semiconductor chips 20a and 20c, the adhesive layer 24b can be prevented more reliably from coming in contact with the semiconductor chips 20a and 20c when the semiconductor chip 20b is bonded to the protrusion 36.

As described above, the semiconductor chips 20a to 20c can be mounted on the die pad 12 having the protrusion 36 with smaller gaps in the X direction between two of the semiconductor chips 20a to 20c adjacent in the X direction. This enables more semiconductor chips to be mounted on the die pad 12.

A semiconductor chip fabricated using a wide bandgap semiconductor has a lower production yield than a semiconductor chip fabricated using silicon. In addition, a wide bandgap semiconductor is more expensive than a silicon semiconductor. Thus, fabricating a single large semiconductor chip using a wide bandgap semiconductor, as in the case of a silicon semiconductor, will result in a poor production yield and a high production cost. The use of a wide bandgap semiconductor will increase the necessity to mount a plurality of small semiconductor chips, instead of a single large semiconductor chip, onto a chip-mount substrate.

In the semiconductor device 10, the semiconductor chips 20a, 20b and 20c, fabricated using a wide bandgap semiconductor, can be arranged efficiently on the single die pad 12. Thus, the structure of the semiconductor device 10 is particularly effective when the semiconductor device 10 includes the semiconductor chips 20a, 20b and 20c fabricated using a wide bandgap semiconductor.

### Second Embodiment

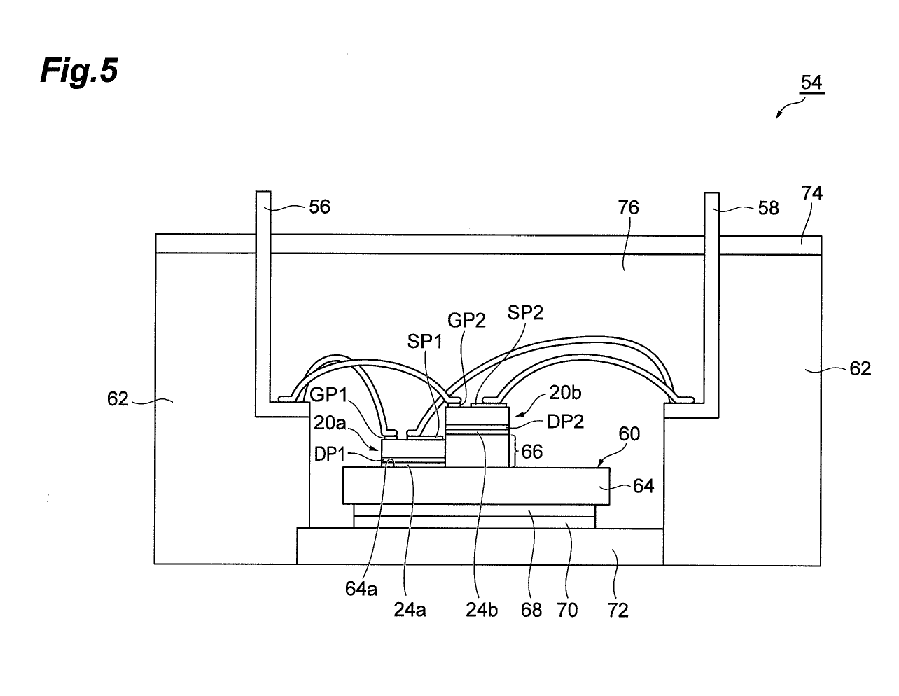

FIG. 5 is a schematic view of a semiconductor device in accordance with a second embodiment of the present invention. The semiconductor device 54 shown in FIG. 5 is a case type semiconductor device. The semiconductor device 54 includes a first semiconductor chip 20a, a second semiconductor chip 20b, a gate electrode terminal 56, an electrode terminal 58, a chip-mount substrate 60, and a case 62.

The chip-mount substrate 60 is a substrate on which the semiconductor chips 20a and 20b are mounted. The chip-mount substrate 60 is a wiring substrate including a wiring layer formed on the surface of an insulating substrate. The semiconductor chips 20a and 20b are arranged on the wiring layer of the chip-mount substrate 60 via adhesive layers 24a and 24b so that the chips are mounted onto the chip-mount substrate 60. Like the die pad 12, the chip-mount substrate 60 includes a base plate 64, and a protrusion 66 provided on the base plate 64. The semiconductor chip 20a is mounted on a main surface 64a of the base plate 64, while the semiconductor chip 20b is mounted on the protrusion 66.

A heat dissipation layer 68 may be provided on a back surface (a surface opposite to the side on which the semiconductor chips 20a and 20b are mounted) of the chip-mount substrate 60. The materials of the heat dissipation layer 68 include metals such as copper and copper alloys. The heat dissipation layer 68 is bonded to a heat sink 72 via an adhesive layer 70 made of, for example, solder or the like. The heat sink 72 may be made of metal.

The semiconductor chips 20a and 20b, the chip-mount substrate 60, and the heat dissipation layer 68 are encased in the case 62. The case 62 has, for example, a cylindrical shape. One opening of the case 62 may be sealed by the heat sink 72. The other opening of the case 62 may be sealed by a lid 74. The case 62 may be made of engineering plastics such as polybutylene terephtahlate (PBT) and polyphenylene sulfide (PPS) resin. The lid 74 may be made of thermoplastic resin. A gel 76, such as silicone gel, may be injected inside the case 62 for stress relaxation.

The gate electrode terminal 56 and the electrode terminal 58 of the semiconductor device 54 are attached to the inner wall of the case 62. The gate electrode terminal 56 and the electrode terminal 58 extend along the inner wall of the case 62 and protrude from the case through openings formed in the lid 74. When the semiconductor chips 20a and 20b include MOS-FETs, the electrode terminal 58 corresponds to the source electrode terminal. The drain electrode terminal is not shown.

The semiconductor device according to the second embodiment has at least the same advantages as the semiconductor device 10.

Although the present invention has been described in detail above in its preferable embodiments, the present invention is not limited to the embodiments described above.

For example, although the semiconductor device 10 includes three semiconductor chips 20a to 20c in the above embodiments, the semiconductor device 10 may not include the semiconductor chip 20c. The semiconductor devices 10 and 54 each may include four or more semiconductor chips. When the semiconductor device includes three or more semiconductor chips, the semiconductor chips may be mounted at positions different in the Z direction. For example, the semiconductor chips 20a and 20c are both mounted on the main surface 34a in FIG. 1. Alternatively, the semiconductor chips 20a and 20c may be mounted at different positions in the Z direction when each of the semiconductor chips 20a and 20c is at a height position different from the height position of the semiconductor chip 20b.

The shape of the protrusion provided on the die pad 12 as a chip-mount substrate and on the chip-mount substrate 60 is not limited to a rectangular parallelepiped. However, the side surface of the protrusion between the first and second semiconductor chips (the side surface in contact with or facing the first semiconductor chip) in the arrangement direction of the adjacent first and second semiconductor chips (X-direction in FIG. 1), which is the direction perpendicular to the thickness direction of the chip-mount substrate, may be substantially perpendicular to the surface on which the first semiconductor chip is mounted. This configuration enables the first and second semiconductor chips to have a still narrower gap between them in the direction in which the chips are arranged.

The die pad 12 as a chip-mount substrate and the chip-mount substrate 60 may have two or more protrusions. In the above embodiments, the second semiconductor chip 20b is mounted on the protrusion of the chip-mount substrate, whereas the first semiconductor chip 20a is mounted in an area of the chip-mount substrate other than the protrusion. As a result, the second semiconductor chip 20b is mounted at the position different from the mounting position of the first semiconductor chip 20a in the Z direction. However, it is only required that the adjacent first and second semiconductor chips 20a and 20b be mounted at different positions in the Z direction. For example, it is only required that the chip-mount substrate have a step in a predetermined direction in which the semiconductor chips are arranged, or in the X direction or the Y direction in FIG. 1.

Although the present invention has been described above in its embodiments, the present invention is not limited to the above embodiments, and various modifications are possible without departing from the spirit of the present invention.

What is claimed is:

1. A semiconductor device, comprising:
a chip-mount substrate;
a first semiconductor chip mounted on the chip-mount substrate; and
a second semiconductor chip mounted adjacent to the first semiconductor chip on the chip-mount substrate,
the chip-mount substrate comprising:
a first surface, the first semiconductor chip being mounted on the first surface; and
a second surface, the second semiconductor chip being mounted on the second surface,
wherein the second surface and the first surface are at different positions in a thickness direction of the chip-mount substrate.

2. The semiconductor device according to claim 1, wherein the second surface is at a higher position than the first surface in the thickness direction, and a difference in the height of the position between the second surface and the first surface in the thickness direction is equal to or greater than a thickness of the first semiconductor chip.

3. The semiconductor device according to claim 1, wherein the chip-mount substrate has a connecting surface that connects the first surface and the second surface, and the connecting surface is perpendicular to the first surface.

4. The semiconductor device according to claim 1, wherein the chip-mount substrate comprises:
a base plate, and
a protrusion provided on a main surface of the base plate, and
wherein the main surface is the first surface, and a surface of the protrusion opposite to the base plate is the second surface.

5. The semiconductor device according to claim 1, wherein a material of the first semiconductor chip and the second semiconductor chip comprises a wide bandgap semiconductor.
